(19) United States
(12) Patent Application Publication
(10) Pub. No.: US 2011/0187452 A1
(43) Pub. Date: Aug. 4, 2011

(54) SOUND AND MUSIC PLAYBACK DEVICE

(75) Inventors: Yukihiro Imai, Kawanishi-shi (JP); Yukio Kadowaki, Nara-shi (JP); Koichi Hagino, Kawanishi-shi (JP); Shunsei Tanaka, Osaka (JP)

(73) Assignee: RICOH COMPANY, LTD., Tokyo (JP)

(21) Appl. No.: 13/014,138

(22) Filed: Jan. 26, 2011

(30) Foreign Application Priority Data
Jan. 29, 2010 (JP) 2010-017793

(51) Int. Cl. H03G 3/20

(52) U.S. Cl. 330/127

(57) ABSTRACT

A sound and music playback device includes: an output amplifier; a power supply circuit that supplies electric power to the output amplifier; and an output signal level judging circuit; wherein an output voltage value of the power supply circuit is changed based on a level of a sound and music signal to be outputted.

### CROSS-REFERENCE TO RELATED APPLICATIONS

The present application is based on and claims priority from Japanese patent application number 2010-017793, filed Jan. 29, 2010, the disclosure of which is hereby incorporated by reference herein in its entirety.

### BACKGROUND

The present invention relates to a sound and music playback device used in a music player and a mobile phone.

In small players such as a mobile phone and a portable music player, low power consumption is demanded. However, in conventional music and sound playback devices, regardless of a playback sound and volume of music, an output voltage value of a power supply circuit that supplies power to an output amplifier is fixed.

That is, in a power supply circuit of such a small player, a fixed output voltage value according to maximum power consumption of the output amplifier is constantly set. Accordingly, in a case where power consumption of the output amplifier is small (in other words, the output volume is small), the power supply circuit supplies more power than necessary to the output amplifier, and as a result, excess power is consumed in the small player.

Japanese patent number 3286924 discloses a terminal device for mobile communication and the like where a frequency characteristic of a sensitivity of a digital sound signal is adjustable and that makes it possible to hear a received sound easily.

Japanese patent number 3788564 discloses a melody sound producing device that makes it possible to improve sound quality of the melody sound composed of a single musical scale.

### SUMMARY

An object of the present invention is to provide a music and sound playback device that keeps power supplied to the output amplifier low by changing the output voltage value of the power supply circuit in conjunction with power consumption of the output amplifier and thereby the low power consumption is achieved.

In order to achieve the above object, an embodiment of the present invention provides a sound and music playback device, comprising: an output amplifier; a power supply circuit that supplies electric power to the output amplifier; and an output signal level judging circuit; wherein an output voltage value of the power supply circuit is changed based on a level of a sound and music signal to be outputted.

### BRIEF DESCRIPTION OF THE DRAWINGS

FIG. 1 is a block diagram of a sound and music playback device according to a first embodiment of the present invention.

FIG. 2 is a block diagram of an output sound volume judging circuit included in the sound and music playback device according to the present invention.

FIG. 3 is a block diagram of a sound and music playback device according to a second embodiment of the present invention.

FIG. 4 is a block diagram of a sound and music playback device according to a third embodiment of the present invention.

FIG. 5 is a block diagram of a sound and music playback device according to a fourth embodiment of the present invention.

### DETAILED DESCRIPTION OF THE PREFERRED EMBODIMENTS

Hereinafter, with reference to the drawings, preferred embodiments according to the present invention will be explained.

### First Embodiment

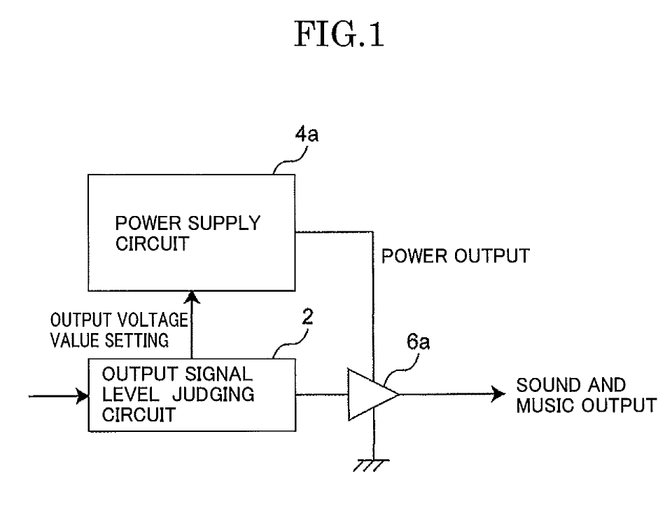

FIG. 1 is a block diagram of a sound and music playback device according to a first embodiment of the present invention. The sound and music playback device illustrated in FIG. 1 includes an output signal level judging circuit 2, a power supply circuit 4, and an output amplifier 6a.

The output signal level judging circuit 2 judges a level of an inputted sound and music signal. Additionally, the output signal level judging circuit 2 sets an output voltage value to the power supply circuit 4a to supply necessary power to the output amplifier 4a to output the sound and music signal in the judged signal level.

The power supply circuit 4a according to the first embodiment outputs a positive voltage to the output amplifier 6a. The output amplifier 6a is grounded. It is preferable that the power supply circuit 4 be a DC-DC converter that outputs positive voltage.

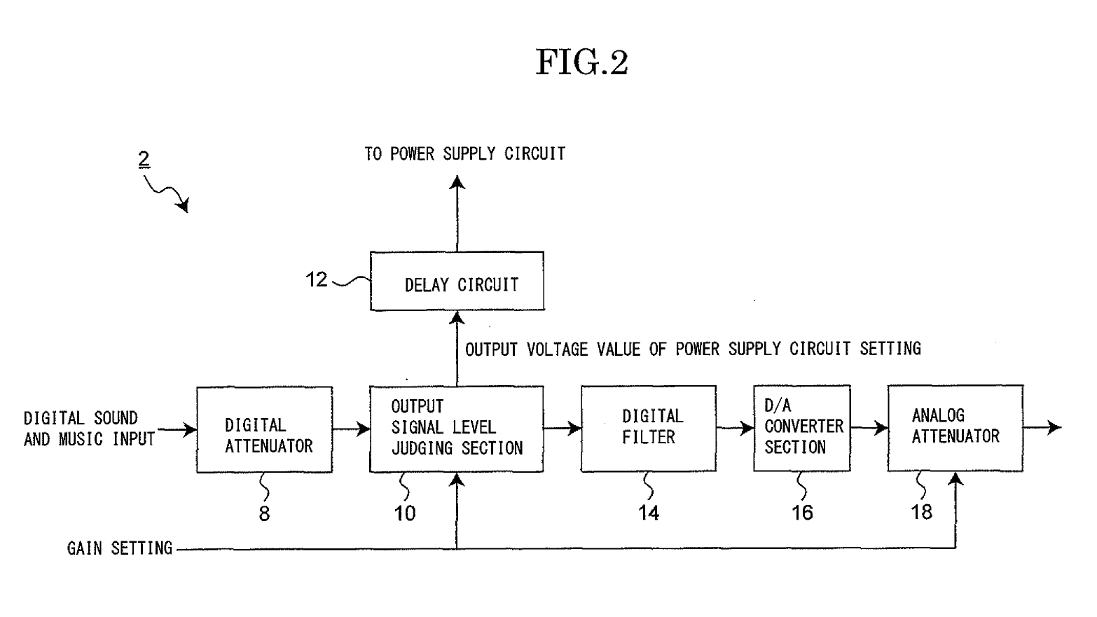

FIG. 2 is a block diagram of an output signal level judging circuit 2 included in the sound and music playback device illustrated in FIG. 1. The output signal level judging circuit 2 illustrated in FIG. 2 is one in a case where the sound and music playback device illustrated in FIG. 1 is a DAC (digital-analog converter) circuit. An output signal level judging circuit according to the present invention can be constructed for a sound and music playback device that processes an analog signal.

The output signal level judging circuit 2 illustrated in FIG. 2 includes a digital attenuator 8, an output signal level judging section 10, a digital filter 14, a D/A (digital-analog) converter section 16, and an analog attenuator 18.

The digital attenuator 8 is a volume controller that controls sound volume (signal level) by digital processing. The output signal level judging section 10 judges whether a signal level is smaller or larger than certain threshold levels (threshold value levels), that is, the output signal level judging section 10 judges an output signal level. The digital filter 14 is a filter circuit provided in an audio DAC circuit. The D/A converter section 16 is a circuit that converts a digital signal to an analog signal. In addition, the analog attenuator 18 is a volume controller that controls sound volume (signal level) by analog processing.

A digital sound and music signal inputted to the output signal level judging circuit 2 is firstly inputted to the digital attenuator 8. The output signal level judging circuit 2 is a part of the audio DAC circuit. The output signal level judging section 10 judges an output signal level of the digital attenuator 8. In addition, “a gain setting value” which is applied to the analog attenuator 18 is inputted to the output signal level judging section 10.

The gain setting value is a volume setting value which is applied to the analog attenuator 18.

Here, “the output signal level of the digital attenuator” is adjusted based on “the gain setting value” of the analog attenuator 18, and the adjusted signal is outputted from the output amplifier 6a eventually.

That is, “the output signal level of the digital attenuator” X ““the gain setting value” of the analog attenuator”.

By the above formula, a signal level of the signal outputted from the output amplifier 6a is calculated, and additionally, the calculated signal level is judged. The output signal level judging circuit 2 determines the output voltage value of the power supply circuit based on the judged signal level.

The output signal level judging circuit 2 illustrated in FIG. 2 additionally includes a delay circuit 12. The delay circuit 12 delays time only equivalent to a processing time in the digital filter 12, the D/A converter section 16, and the analog attenuator 18 for setting the output voltage value to the power supply circuit 4a. This makes it possible to adjust timing of a movement in the output amplifier 6a and a movement in the power supply circuit 4a.

As for power supply from the power supply circuit 4a, a delay time of the time delay circuit 12 can be set differently to a case of transition “from a supply of large power to a supply of small power” and a case of transition “from a supply of small power to a supply of large power”. That is, the case of transition “from the supply of small power to the supply of large power” is when an amplitude of an output signal is changed from small to large, and in this case, the delay time is shortened, and a power supply voltage of the power supply circuit 4a is quickly changed to the case of transition “from the supply of small power to the supply of large power”. This is to avoid such a problem that regardless of only the supply of small power, in a case where a signal of a large amplitude is outputted from the output amplifier 6a, an output signal of the output amplifier 6a is distorted, as much as possible.

On the other hand, the case of transition “from the supply of large power to the supply of small power” is when the amplitude of the output signal is changed from large to small, and in this case, the delay time is lengthened, and the power supply voltage of the power supply circuit 4a is slowly changed to the case of transition “from the supply of large power to the supply of small power”. This is because regardless of the signal of the large amplitude being outputted from the output amplifier 6a, in a state where only small power is supplied, and the output signal of the output amplifier 6a is distorted.

It is preferable that the delay time set by the time delay circuit 12 be set corresponding to each of the case of transition “from the supply of small power to the supply of large power” and the case of transition “from the supply of large power to the supply of small power” by a register setting and so on from outside.

And, priority given to either power consumption or sound quality can be set from outside, and a priority degree of the power consumption and the sound quality can be set from outside.

That is, regarding the priority degree, in a case where the priority is given to the sound quality, the delay time of the case of transition “from the supply of small power to the supply of large power” is set to be shorter and the delay time of the case of transition “from the supply of large power to the supply of small power” is set to be longer, so that a state of the supply of large power is lengthened.

In a case where the priority is given to the power consumption (low power consumption), the delay time of the case of transition “from the supply of small power to the supply of large power” is set to be a little longer than in the case where the priority is given to the sound quality, and the delay time of the case of transition “from the supply of large power to the supply of small power” is set to be a little shorter than in the case where the priority is given to the sound quality, so that a state of the supply of small power is lengthened.

By use of the above-described sound and music playback device, the output voltage value of the power supply circuit 4a is changed in conjunction with the power consumption of the output amplifier 6a, and the power supplied to the output amplifier 6a is kept low, and thereby low power consumption is achieved.

Between the power supply circuit 4a and the output amplifier 6a, a low voltage circuit constructed by a LDO (Low Drop Out) and so on can be provided.

### Second Embodiment

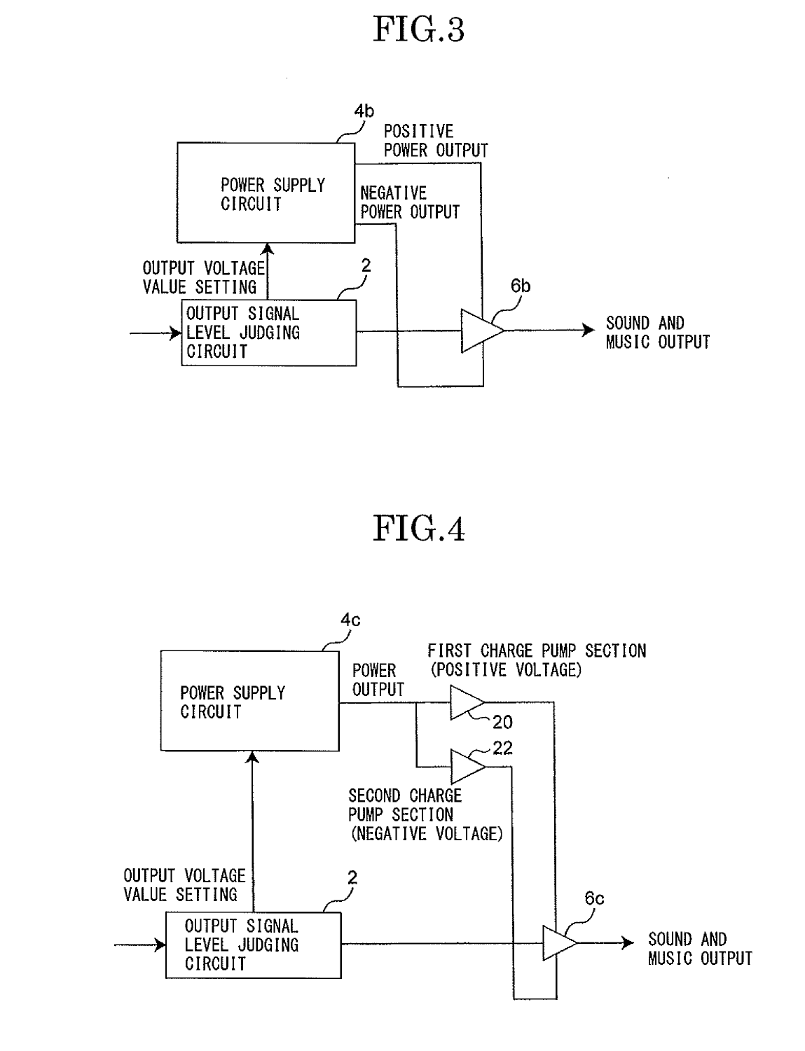

FIG. 3 is a block diagram of a sound and music playback device according to a second embodiment of the present invention. The sound and music playback device illustrated in FIG. 3 is approximately the same as the sound and music playback device according to the first embodiment. Therefore, the same parts are denoted by the same reference numbers, and an explanation will be omitted here.

A power supply circuit 4b according to the second embodiment is a DC-DC converter that outputs positive power (voltage) and negative power (voltage) to an output amplifier 6b. And the power supply circuit 4b illustrated in FIG. 3 outputs an output voltage around 0V. And a sound and music output signal outputted from the output signal level judging circuit 2 is inputted to the output amplifier 6b around 0V. By employing a circuit construction as the above, it is no longer necessary to provide a DC cut capacitor used in the case of connecting to headphones or speakers, and therefore the number of components is reduced.

Also in the sound and music playback device according to the second embodiment, between the power supply circuit 4b and the output amplifier 6b, a low voltage circuit constructed by a LDO (Low-Dropout) regulator and so on can be provided.

### Third Embodiment

FIG. 4 is a block diagram of a sound and music playback device according to a third embodiment of the present invention. The sound and music playback device illustrated in FIG. 4 is approximately the same as the sound and music playback device according to the second embodiment. Therefore, the same parts are denoted by the same reference numbers, and an explanation will be omitted here.

The power supply circuit 4c according to the third embodiment outputs positive power (voltage). In addition, in the power supply circuit 4c according to the third embodiment, two charge pump sections (that is, a first charge pump section 20 and a second charge pump section 22) are provided, and each outputs positive power and negative power, respectively. The positive power and the negative power outputted respectively from the two charge pump parts, the first charge pump part 20 and the second charge pump part 22 are inputted to the output amplifier 6c.

The sound and music output signal outputted from the output signal level judging circuit 2 is also inputted to the output amplifier 6c illustrated in FIG. 4 around 0V. By employing a circuit construction as described above, it is no longer necessary to provide a DC cut capacitor used in the case of connecting to headphones or speakers, and therefore the number of components is reduced.

And also in the sound and music playback device according to the third embodiment, between the charge pumps 20 and 22 and the output amplifier 6c, a low voltage circuit constructed by a LDO (Low-Dropout) regulator and so on can be provided.

### Fourth Embodiment

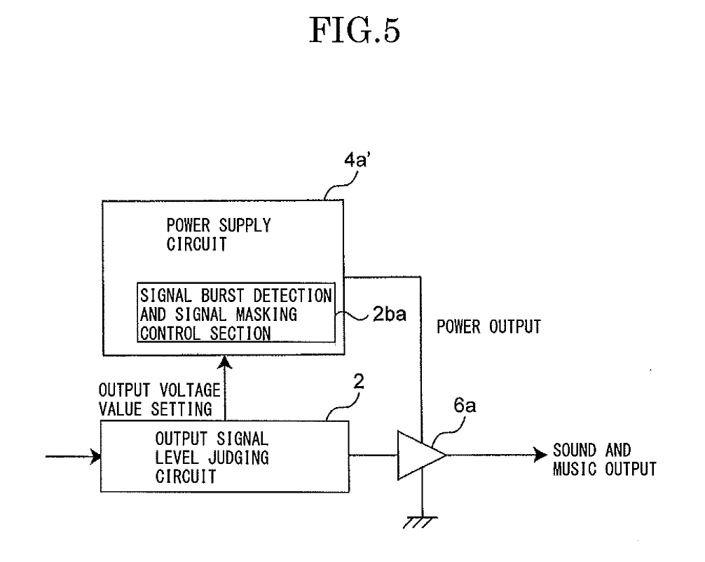

FIG. 5 is a block diagram of a sound and music playback device according to a fourth embodiment of the present invention. The sound and music playback device illustrated in FIG. 4 is approximately the same as the sound and music playback device according to the first embodiment. Therefore, the same parts are denoted by the same reference numbers, and an explanation will be omitted here.

In a power supply circuit 4a′ according to the fourth embodiment illustrated in FIG. 5, a signal burst detection and signal masking control section 26a is provided. This signal burst detection and signal masking control section 26a is a circuit section that performs a detection of a cycle of a signal burst and a signal masking control based on the cycle of the signal burst.

That is, in a power supply circuit, in a case where a signal burst occurs when an output voltage is low (that is, in the case of low load), when the signal burst occurs in a cycle and the cycle (frequency) of the signal burst enters the audio range, the number of signal bursts is controlled to be reduced by masking. The cycle of the signal burst is adjusted and shifted outside of the audio range. And therefore noise by the signal burst is reduced.

Entering the audio range of the frequency of the signal burst is judged by an interval of a switching of the power supply circuit.

That is, a case where there is a next switching immediately after a certain switching, this is recognized as “a signal burst”. After the signal burst is repeated, the load of the power supply circuit is reduced, and in a case where a clock is stopped by a skip operation, the switching operation of the power supply circuit is stopped, and an interval between a certain switching and a next switching after the certain switching becomes longer. The interval of this switching operation is detected. In a case where this interval (frequency) is a frequency lower than the audio range (20 Khz (500 uS)), a masking operation is started.

When an interval (frequency) between the above-described signal burst and the next switching is detected, and it is judged that the frequency enters the audio range, a next clock is outputted normally, and a clock after the next clock is not outputted. Therefore, after recognition of the signal burst, in a case where a switching occurs in the audio range, the signal burst can be stopped by the next switching. It is preferable that an interval of masking be for about 10 clocks, and be controlled by random numbers.

If a switching operation based on the signal burst is performed without performing the above-described masking control, a capacitor (not illustrated) that is connected to stabilize a voltage output is overcharged by the power supply circuit through a coil (not illustrated). In the case of light load, because the speed of consuming charges charged in the capacitor is slow, the speed of voltage reduction of the capacitor is slow. Therefore, a period until a start instruction of a next switching of the power supply circuit occurs (a period where a clock is stopped by a skip operation if the power supply circuit is a skip type) becomes longer, as a result, there is a case where the frequency of the signal burst enters the audio range.

Accordingly, the switching operation by the signal burst is restrained, and only a single switching is performed, and therefore a charge amount of the capacitor is kept optimally, and the interval of switching is shortened.

The sound and music playback device can be used for a mobile phone, a portable music player, a notebook computer, and a portable image playback device.

In the sound and music playback device according to the embodiments of the present invention, since electric power is supplied from the power supply circuit to the output amplifier based on the level (sound volume) of the sound and music signal to be outputted, in a case where the output amplifier can be operated by small power, that is, in a case where the output signal level of the output amplifier is small, supplied electric power is kept low, and therefore it is possible to achieve low power consumption.

In addition, in the sound and music playback device according to the embodiments of the present invention, it is possible to output the sound and music signal to be outputted around 0V, and therefore, it is not necessary to provide the capacitor used in the case of connecting to the headphones and the speakers, and it is possible to reduce the number of components.

Additionally, in the power supply circuit, in a case where a signal burst occurs when output voltage is low (that is, in the case of low load), the signal burst occurs in a cycle, and the cycle (frequency) enters the audio range, and there is such a case that a sound and music playback device generates a large amount of noise.

In the sound and music playback device according to the embodiments of the present invention, the cycle of the signal burst is adjusted and shifted outside of the audio range. And therefore noise by the signal burst is reduced.

Although the present invention has been described in terms of exemplary embodiments, it is not limited thereto. It should be appreciated that variations may be made in the embodiments described by persons skilled in the art without departing from the scope of the present invention as defined by the following claims.

What is claimed is:

1. A sound and music playback device, comprising:
an output amplifier;
a power supply circuit that supplies electric power to the output amplifier; and
an output signal level judging circuit;
wherein an output voltage value of the power supply circuit is changed based on a level of a sound and music signal to be outputted.

2. The sound and music playback device according to claim 1, wherein the output signal level judging circuit includes: a digital attenuator; and an analog attenuator, and the output signal level judging circuit determines the output voltage value based on an output signal level of the digital attenuator and a gain setting value which is applied to the analog attenuator.

3. The sound and music playback device according to claim 2, wherein the output signal level judging circuit further includes: a delay circuit, and a delay time of the delay circuit is set from outside of the output signal level judging section.

4. The sound and music playback device according to claim 3, wherein the power supply circuit is a DC-DC converter that outputs a positive voltage.

5. The sound and music playback device according to claim 3, wherein the power supply circuit is a DC-DC converter that outputs a positive voltage and a negative voltage.

6. The sound and music playback device according to claim 3, further comprising:
a first charge pump section; and
a second charge pump section;
wherein the power supply circuit is a DC-DC converter that outputs a positive voltage, and the first charge pump circuit section outputs a positive voltage from the voltage outputted from the DC-DC converter, and the second charge pump circuit section outputs a negative voltage from the voltage outputted from the DC-DC converter.

7. The sound and music playback device according to claim 4, wherein a low voltage circuit is provided between the power supply circuit and the output amplifier.

8. The sound and music playback device according to claim 4, wherein the power supply circuit includes a signal burst detection and signal masking control section that in a case where an output of the power supply circuit is signal-burst, and a frequency of a signal burst enters an audio range, shifts the frequency of the signal burst outside of the audio range by performing a masking control on the signal burst.
